(19) United States
(12) Patent Application Publication
(10) Pub. No.: US 2007/0169960 A1
(43) Pub. Date: Jul. 26, 2007

(54) Multilayer stacked wiring board

(75) Inventor: Katsuhiko Hayashi, Saitama (JP)

Correspondence Address: THE WEBB LAW FIRM, P.C., 700 KOPPERS BUILDING, 436 SEVENTH AVENUE, PITTSBURGH, PA, 15219, US

(73) Assignee: Mitsui Mining & Smelting Co., Ltd., Shinagawa-ku (JP)

(21) Appl. No.: 10/590,627

(22) PCT Filed: Feb. 15, 2005
(86) PCT No.: PCT/JP05/02205

§ 371 Date: Aug. 24, 2006

(30) Foreign Application Priority Data
Feb. 26, 2004 (JP) 2004-051554

(51) Int. Cl. H05K 1/11

(52) U.S. Cl. 174/262

(57) ABSTRACT

A multilayer wiring board comprising at least two double-sided wiring boards which comprises an insulating substrate and conductive metal wiring patterns on both surfaces of the insulating substrate. The wiring patterns on the insulating substrate are connected through a conductive metal in a through hole through the insulating substrate. The double-sided wiring boards are electrically connected by joining of low-melting conductive metal layers on connection terminals at the mating surfaces of the double-sided wiring boards. The at least two double-sided wiring boards are bonded by means of a polyimide adhesive resin that is selectively applied by screen printing on the double-sided wiring boards other than on the connection terminals. The wiring boards are reliably laminated, and the multilayer wiring board has a reliable electrical connection between the wiring boards.

### TECHNICAL FIELD

The present invention relates to a multilayer wiring board comprising at least two electrically connected wiring boards comprising an insulating film and wiring patterns on both surfaces of the insulating film.

### BACKGROUND ART

When electronic components, for example IC chip, are mounted, film carrier tapes for mounting electronic components such as TAB (tape automated bonding) tapes, CSP (chip size package) tapes, BGA (ball grid array) tapes and FPC (flexible printed circuit), laminates of these tapes, and multilayer wiring boards having rigid substrates such as glass epoxy are used.

The multilayer wiring boards are manufactured as follows. A double-sided copper clad laminate having sprocket holes is provided. Both surfaces-of the laminate are coated with a photoresist, and the photoresist layers are exposed to light and developed to form desired patterns. The copper clad laminate is then etched using the patterns as masks. Consequently, wiring patterns are formed on both surfaces of the insulating substrate (film). The thus formed double-sided wiring boards are laminated through an insulating layer, and an electrical connection is established between the double-sided wiring boards. To establish electrical connections between the wiring patterns, Patent Document 1 (JP-A-2002-343901) discloses a process in which a bump-forming conductive material is placed in the vicinity of a substrate of a printed wiring board; the conductive material is punched, and substantially simultaneously through holes are formed in the substrate and are filled with the bump-forming conductive material to form a desired number of bumps in the substrate; and a plurality of printed wiring board units are laminated via connection parts and are pressure bonded under heating to manufacture CSP.

In the above process, the bump-forming conductive material and the substrate are punched out substantially at the same time, and consequently through holes are formed and are simultaneously filled with the bump-forming conductive material. The wiring patterns on both surfaces of the insulating substrate have a very good electrical connection. However, laminating the printed wiring board units often results in failure of reliable electrical connection between the printed wiring board units through the bump-forming conductive material filled in the through holes. Namely, the bump-forming conductive material filled in the through holes is often incapable of achieving an adequate electrical connection with the surface of the wiring patterns of the mating printed wiring board units. It is therefore difficult that a laminate of such printed wiring board units achieve a stable electrical connection between the units. Providing a stable connection entails very complicated steps, and efficient production of reliable multilayer wiring boards is difficult.

The laminate described above includes a plurality of the printed wiring board units with an insulating layer in between. The insulating layers used in the laminates have shown unsatisfactory properties. For example, when a high-frequency current is applied to the laminates, properties of the insulating layers are often responsible for deteriorating characteristics of the multilayer wiring boards.

In particular, the multilayer wiring boards having polyimide insulating substrates are often strained by the internal stress which is a result of the curing of insulating adhesives used in laminating the printed wiring board units. If the insulating adhesives have low insulating properties, sufficient insulation may not be obtained when a high-frequency current is applied. As described above, the conventional processes have been incapable of ensuring an electrical connection between the printed wiring board units of the multilayer wiring board. Furthermore, concerning the insulating adhesives for laminating the printed wiring board units, it must be selected in view of characteristics and use of current electronic components and must be selected such that the electrical connection between the printed wiring board units will be ensured.

Patent Document 2 (JP-A-H11-163529), Patent Document 3 (JP-A-H11-163213) and Patent Document 4 (JP-A-2002-76557) disclose other types of multilayer wiring boards. However, they require very intricate production steps and are not suited for the industrial mass production of stable multilayer wiring boards.

As described above, the conventional multilayer wiring boards entail many and complicated steps for laminating a substrate having wiring patterns thereon, and hardly achieve a stable electrical connection between the wiring boards. Manufacturing of the stable multilayer wiring boards is not necessarily easy.

Patent Document 1: JP-A-2002-343901

Patent Document 2: JP-A-H11-163529

Patent Document 3: JP-A-H11-163213

Patent Document 4: JP-A-2002-76557

### DISCLOSURE OF THE INVENTION

### Problems to be Solved by the Invention

It is an object of the present invention to provide a multilayer wiring board that is easily producible by laminating wiring boards and has a reliable electrical connection between the wiring boards.

Specifically, it is an object of the present invention to provide a multilayer wiring board having a reliable electrical connection between the wiring boards, and having a reliable bonding of the double-sided wiring boards, which maintains high characteristics even when a high frequency is applied.

### Means for Solving the Problems

A multilayer wiring board according to the present invention comprises at least two wiring boards,

each of the wiring boards comprising an insulating substrate and a wiring pattern which comprises a conductive metal,

at least one of the at least two wiring boards having the wiring patterns on both surfaces of the insulating substrate,

at least part of the wiring patterns on the insulating substrate being connected via a conductive metal in a through hole through the insulating substrate,

the wiring boards being electrically connected by joining of low-melting conductive metal layers on connection terminals at the mating surfaces of the wiring boards, and

the at least two wiring boards being bonded by means of a polyimide adhesive resin that is selectively applied by screen printing on the wiring boards other than on the connection terminals.

A multilayer wiring board according to the present invention comprises at least two double-sided wiring boards,

each of the double-sided wiring boards comprising an insulating substrate and wiring patterns which comprises a conductive metal on both surfaces of the insulating substrate,

the wiring patterns on the insulating substrate being connected via a conductive metal in a through hole through the insulating substrate,

the double-sided wiring boards being electrically connected by joining of low-melting conductive metal layers on connection terminals at the mating surfaces of the double-sided wiring boards, and

the at least two double-sided wiring boards being bonded by means of a polyimide adhesive resin that is selectively applied by screen printing on the double-sided wiring boards other than on the connection terminals.

In the present invention, at least two double-sided wiring boards may be laminated. The outer surface of the outermost wiring board may be free from a wiring pattern. That is, the present invention includes an embodiment in which the multilayer wiring boards have an odd number of wiring patterns, for example three or five wiring patterns, across the thickness.

In the present invention, the double-sided conductive substrate comprises the insulating film such as a polyimide film that is sandwiched between conductive metal layers such as copper layers. Preferably, the electrical conduction between both surfaces of the double-sided conductive substrate is established by a series of steps in which a conductive metal foil such as a copper foil is placed on the substrate and is punched out, and the conductive metal foil pieces punched out punch out the double-sided conductive substrate and are inserted in the double-sided conductive substrate. Alternatively, the electrical conduction is preferably made by a series of steps in which the insulating substrate or the double-sided metal clad laminate is previously provided with through holes; a conductive metal foil is placed on the substrate or laminate and is punched out; and the conductive metal pieces punched out are inserted in the through holes in the insulating substrate or the double-sided metal clad laminate.

In the multilayer wiring board of the present invention, the electrical connection between the double-sided wiring boards preferably takes place at locations where the conductive metal foil pieces are inserted for electrically connecting the two surfaces of each wiring board. Low-melting conductive metal layers are formed on connection surfaces, and a specific polyimide adhesive resin is applied selectively by screen printing. The double-sided wiring boards are pressure bonded under heating to produce a multilayer wiring board reliably.

### Effects of the Invention

According to the present invention, the multilayer wiring board having high reliability can be obtained by very simple steps. That is to say, the multilayer wiring board in which the wiring patterns on both surfaces of the insulating substrate are electrically connected through the conductive metal pieces inserted in the via holes is producible very easily.

### BRIEF DESCRIPTION OF THE DRAWINGS

FIG. 1 is a sectional view illustrating wiring boards in steps of producing a multilayer wiring board according to the present invention;

FIG. 2 is a sectional view in which via holes are formed in an insulating substrate and metal pieces are inserted in the via holes, and thereafter conductive metal layers are formed and patterned to form wiring patterns;

FIG. 3 is a sectional view in which via holes are formed in an insulating substrate having conductive metal layers on both surfaces and metal pieces are inserted in the via holes to establish an electrical connection between the two surfaces of the insulating substrate;

FIG. 4 is a schematic sectional view of a multilayer wiring board produced in Example 2;

FIG. 5 is a schematic sectional view of a multilayer wiring board produced in Example 3;

FIG. 6 is a graph showing the resistance of the multilayer wiring board produced in Example 3 across its thickness;

FIG. 7 is a schematic sectional view of a multilayer wiring board produced in Example 4; and

FIG. 8 is a graph showing the resistance of the multilayer wiring board produced in Example 4 across its thickness.

### DESCRIPTION OF CODES

10 . . . Insulating substrate
12a, 12b . . . Conductive metal layer
13 . . . Double-sided metal clad laminate
14a, 14b . . . Pattern
15a, 15b . . . Wiring pattern
20 . . . Double-sided wiring board
20-1, 20-2 . . . Double-sided wiring board
21 . . . Through hole
22 . . . Conductive metal piece
25 . . . Conductive metal foil
30 . . . Punch
30a, 30b, 30c, 30d . . . Connection terminal (wiring pattern)
33 . . . Low-melting conductive metal layer
34 . . . Connection metal layer
35-1, 35-2 . . . Adhesive layer
35 . . . Adhesive layer
42a, 42b . . . Conductive metal layer
43 . . . Double-sided metal clad laminate
50 . . . Multilayer wiring board

### BEST MODE FOR CARRYING OUT THE INVENTION

The multilayer wiring boards according to the present invention will be described with reference to the figures.

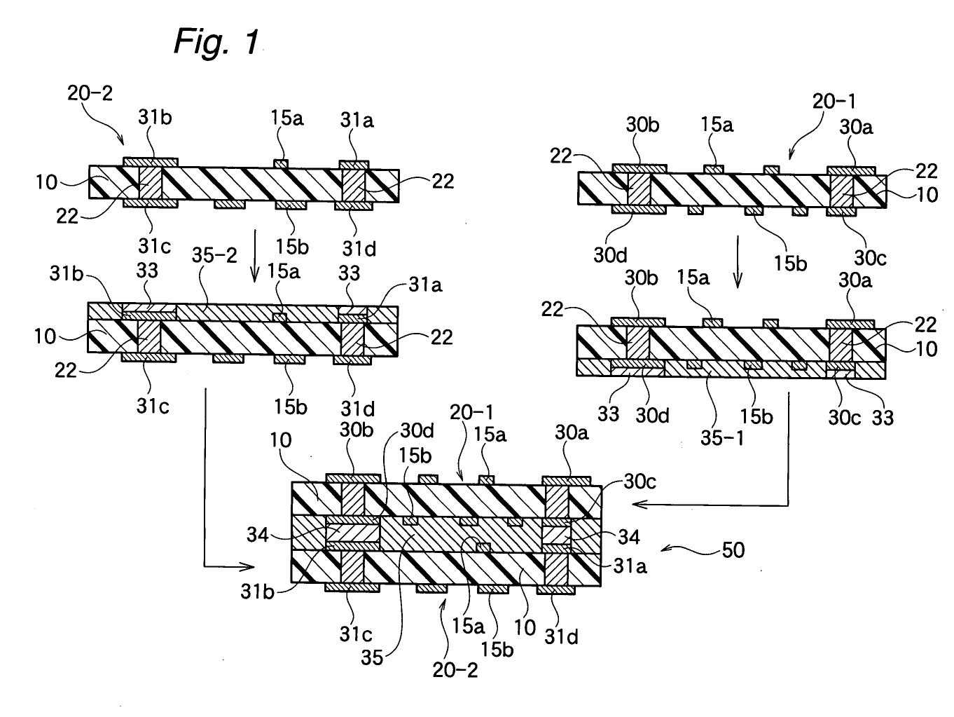

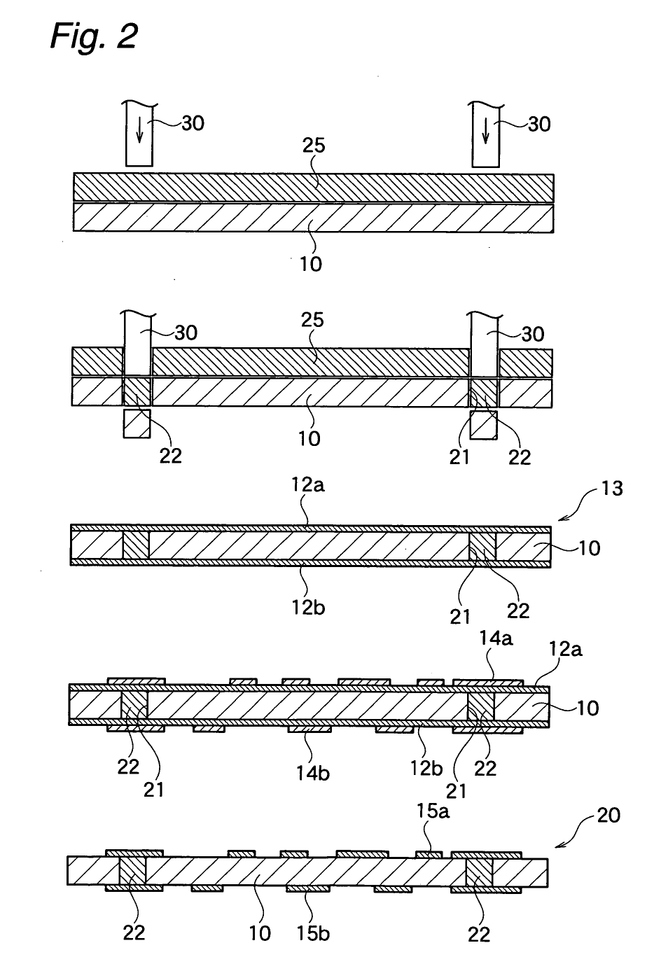

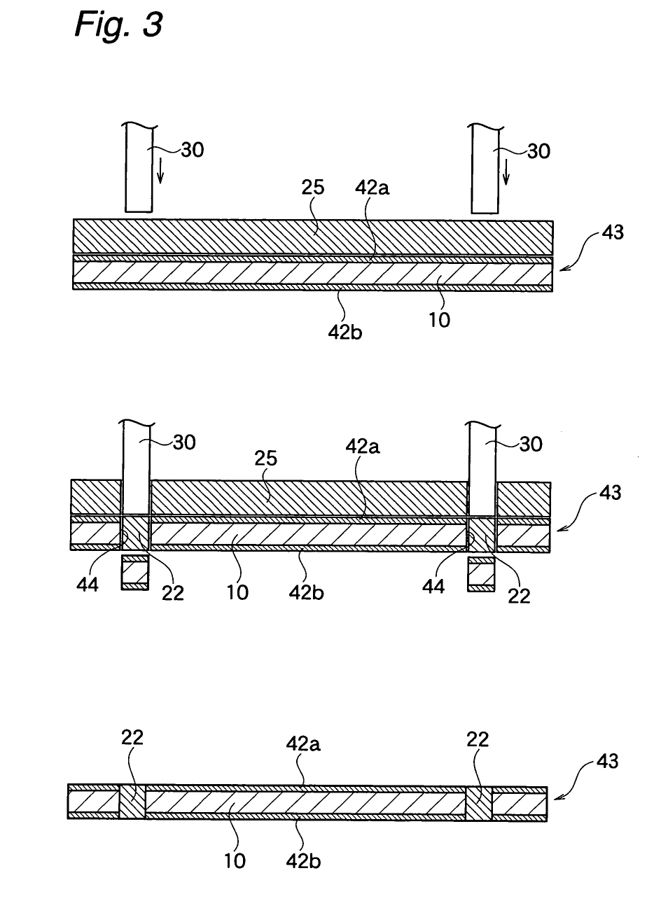

FIG. 1 is a sectional view illustrating wiring boards in steps of producing a multilayer wiring board according to the present invention. FIGS. 2 and 3 are sectional views illustrating composite substrates used for the manufacturing of the multilayer wiring board according to the present invention.

As shown in FIGS. 1 and 2, a double-sided metal clad laminate 13 comprises an insulating substrate 10 and conductive metal layers 12a and 12b on both surfaces of the substrate. The conductive metal layers 12a and 12b on the insulating substrate 10 are selectively etched, and consequently wiring patterns 15a and 15b are formed on both surfaces of the insulating substrate 10. At least two such double-sided wiring boards 20 are laminated.

The double-sided wiring board 20 of the present invention has through holes 21 that establish electrical conduction between the two surfaces of the insulating substrate 10. Conductive metal pieces 22 are inserted in the through holes 21. Consequently, the wiring patterns 15a and 15b on the front and back surfaces of the insulating substrate 10 are electrically connected at locations required.

The conductive metal pieces 22 may be inserted in the through holes 21 in the insulating substrate 10 as illustrated in FIG. 2. A conductive metal foil 25 is placed on the surface of the insulating substrate 10. The conductive metal foil 25 and the insulating substrate 10 are punched with punches 30 simultaneously such that the conductive metal pieces 22 to be inserted in the insulating substrate 10 will be punched out and will function as tips of the punches to punch out the insulating substrate 10 and to form the through holes 21 in the insulating substrate 10, and the pieces 22 will remain in the through holes 21 in the insulating substrate 10. The conductive metal pieces 22 remaining in the through holes 21 work as means for electrically connecting wiring patterns 15a and 15b that will be formed on both surfaces of the insulating substrate 10. The punches for forming the through holes 21 are approximately from 1 to 1000 μm, preferably from 10 to 500 μm in diameter, whereby very fine through holes are formed. The conductive metal foil 25 has a thickness equal to or slightly greater than that of the insulating substrate 10. The electrical conduction across the thickness of the insulating substrate may be alternatively established as follows. The insulating substrate 10 is perforated with punches or the like to form through holes. The conductive metal foil 25 is placed on the perforated insulating substrate 10 and is punched with the punches 30 such that the conductive metal pieces 22 to be inserted in the insulating substrate 10 will be punched out and will remain in the through holes in the insulating substrate 10. The conductive metal pieces work as means for electrically connecting wiring patterns that will be provided on both surfaces of the insulating substrate 10.

The insulating substrates 10 used in the present invention may be synthetic resin films having excellent heat resistance, chemical resistance, and humidity and heat stability. Examples of the synthetic resin films include polyimide films, polyamideimide films, heat-resistant polyester films, BT resin films, phenolic resin films and liquid crystal polymer films. Of these, in the present invention polyimide films are preferable because of their prominent heat resistance, chemical resistance, and humidity and heat stability. The insulating substrate 10 generally has a thickness of 5 to 150 μm, preferably 5 to 125 μm. The conductive metal foil 25 placed on the insulating substrate 10 has a thickness equal to or slightly greater than that of the insulating substrate 10. Specifically, the conductive metal foil 25 generally has a thickness of 50 to 200 μm, preferably 80 to 120 μm. That is, the conductive metal foil 25 is generally 100 to 300% thicker, preferably 200 to 240% thicker than the insulating substrate 10. When the slightly thicker conductive metal foil 25 is used, both ends of the conductive metal pieces 22 slightly protrude from the surfaces of the insulating substrate 10. The exposed protrusions can be caulked to prevent detachment of the conductive metal pieces 22 from the through holes 21.

After the conductive metal pieces 22 are inserted in the through holes 21 formed in the insulating substrate 10, the conductive metal layers 12a and 12b are formed over the surface of the insulating substrate 10 to cover the conductive metal pieces 22. The conductive metal layers 12a and 12b may be formed by laminating conductive metal foils on the insulating substrate 10. Alternatively, the surfaces of the insulating substrate 10 may be plated with a conductive metal such as copper or aluminum by using plating technique. Moreover, the conductive metal layers 12a and 12b may be formed by depositing a conductive metal on the surfaces of the insulating substrate 10 by using deposition technique. The conductive metal layers 12a and 12b may be single layers of a conductive metal or laminates of a plurality of conductive metal layers.

FIG. 3 shows another embodiment of the present invention. A double-sided metal clad laminate 43 is provided which comprises an insulating substrate 10 and conductive metal layers 42a and 42b on the surface of the insulating substrate. A conductive metal foil 25 is placed on the surface of the double-sided metal clad laminate 43. The conductive metal foil 25 and the double-sided metal clad laminate 43 are punched with punches 30 simultaneously such that conductive metal pieces 22 to be inserted in the double-sided metal clad laminate 43 will be punched out and will function as tips of the punches 30 to punch out the double-sided metal clad laminate 43 and to form through holes 21 in the double-sided metal clad laminate 43, and the pieces 22 will remain in the through holes 21 in the double-sided metal clad laminate 43. The conductive metal pieces 22 remaining in the through holes 21 electrically connect the conductive metal layers 42a and 42b on both surfaces of the insulating substrate 10. Subsequently, the board is plated with copper or the like in a thickness of 3 to 6 μm to enhance connection reliability between the conductive metal layers and the conductive metal pieces 22. The plating metals include nickel, solder, lead-free solder and tin.

The double-sided metal clad laminate 43 may be manufactured by laminating conductive metal foils on both surfaces of the insulating substrate, or by depositing conductive metals on both surfaces of the insulating substrate by using plating or deposition. The conductive metal layers may be single layers of a conductive metal such as copper, copper alloy or aluminum, or may be laminates of a plurality of different conductive metal layers. The electrical conduction across the thickness of the insulating substrate of the present invention may be alternatively established as follows. The double-sided metal clad laminate 43 is perforated with punches or the like to form through holes. The conductive metal foil 25 is placed on the perforated laminate and is punched with the punches 30 such that the conductive metal pieces 22 are punched out and are inserted in the through holes 21 in the double-sided metal clad laminate 43. The conductive metal pieces 22 remaining in the through holes 21 work as means for electrically connecting the conductive metal layers 42a and 42b on both surfaces of the insulating substrate 10.

The conductive metal layers 12a, 12b, 42a and 42b thus formed are generally from 4 to 35 μm, preferably from 6 to 15 μm in thickness.

The double-sided wiring boards 20 for manufacturing a multilayer wiring board 50 of the present invention are produced as follows. Using the double-sided metal clad laminates 13 having the conductive metal layers 12a and 12b on both surfaces, or the double-sided metal clad laminates 43 having the conductive metal layers 42a and 42b on both surfaces, for example, photoresist layers are formed on the conductive metal layers 12a and 12b as shown in FIG. 2, and are exposed to light and developed to form photoresist patterns 14a and 14b on the conductive metal layers 12a and 12b. The conductive metal layers 12a and 12b are selectively etched using the patterns 14a and 14b as masks. Referring to FIG. 2, the wiring patterns 12a and 12b on the front and back surfaces of the insulating substrate 10 are electrically connected through the conductive metal pieces 22 filled in the insulating substrate 10.

The multilayer wiring board 50 according to the present invention comprises at least two double-sided wiring boards 20. FIG. 1 illustrates lamination of two double-sided wiring boards 20-1 and 20-2.

The double-sided wiring board 20-1 on the right side in FIG. 1 has the wiring pattern 15b on the back surface, to which the double-sided wiring board 20-2 on the left side is laminated. Specifically, a wiring (connection terminal) 30d and a wiring (connection terminal) 30e are to be connection terminals. The double-sided wiring board 20-2 has the wiring pattern 15a on the front surface, to which the mating wiring board is laminated. Specifically, a wiring (connection terminal) 31d and a wiring (connection terminal) 31c are to be connection terminals.

To establish an electrical connection between the double-sided wiring boards 20-1 and 20-2 that are laminated, low-melting conductive metal layers 33 are formed on the surface of the connection terminals 30d and 30e on the back surface of the double-sided wiring board 20-1, and the surface of the connection terminals 31a and 31b on the front surface of the double-sided wiring board 20-2. The low-melting conductive metal layers 33 are generally composed of a metal or alloy having a melting point of not more than 300° C., preferably from 180 to 240° C. Examples of the low-melting metals and alloys include solder, lead-free solder, tin, gold and nickel-gold. The low-melting conductive metal layers 33 may include one or more metals and alloys in combination. That is, the low-melting conductive metal layers 33 may be single layers of these metals or alloys, or laminates of a plurality of such layers.

The low-melting conductive metal layers 33 of the above metals or alloys may be formed on the connection terminals 30d, 30e, 31a and 31b by various methods. In the present invention, plating is advantageous for forming the low-melting conductive metal layers 33. When forming the low-melting conductive metal layers 33 by plating, the surface of the wiring patterns 15a and 15b that are on the double-sided wiring boards 20-1 and 20-2 and do not participate in the electrical connection between the double-sided wiring boards 20-1 and 20-2 is preferably protected by resin films or the like. That is to say, the connection terminals 30d and 30e, and the connection terminals 31a and 31b are selectively exposed from the surface of the double-sided wiring boards 20-1 and 20-2, and the other area is coated with the resin, followed by plating. The selective application of the protective resin maybe performed using screen masks masking the connection terminals 30d and 30e, and the connection terminals 31a and 31b. According the present invention, the protective resin may be a polyimide adhesive resin, which is used for forming adhesive layers as will be described later. It is preferable that the polyimide adhesive resin is applied through screen masks as described, and is cured temporarily by heating.

The connection terminals 30d and 30e, and the connection terminals 31a and 31b are selectively exposed from the surface of the double-sided wiring boards 20-1 and 20-2 as described above. The double-sided wiring boards 20-1 and 20-2 are immersed in a plating solution containing a desired metal, and the connection terminals 30d and 30e, and the connection terminals 31a and 31b are plated, resulting to form the low-melting conductive metal layers 33. Particularly preferably, in the present invention the low-melting conductive metal layer 33 is at least one plated metal layer selected from the group consisting of plated solder layer, plated lead-free solder layer, plated tin layer, plated gold layer and plated nickel-gold layer. Particularly, in the present invention the low-melting conductive metal layer 33 is preferably a plated solder layer or a plated lead-free solder layer. The low-melting conductive metal layers 33 may be formed by electroplating or electroless plating.

The thickness of the low-melting conductive metal layers 33 thus formed may be determined appropriately depending on the metal or alloy used. Generally, the thickness is in the range of 0.5 to 10 μm, preferably 3 to 6 μm. This thickness permits the low-melting conductive metal layers 33 to ensure good electrical connection between the double-sided wiring boards 20-1 and 20-2, and prevents short-circuits by excess low-melting conductive metal in establishing the electrical connection.

The first conductive metal layers are formed on the electrical connection surface of the double-sided wiring board 1. The second conductive metal layers are formed on the electrical connection surface of the mating double-sided wiring board that is to be electrically connected with the double-sided wiring board 1. Preferably, the first and the second conductive metal layers have at least one combination selected from the group consisting of plated solder layers/plated nickel-gold layers, plated tin layers/plated nickel-gold layers, plated solder layers/plated solder layers, plated tin layers/plated nickel-gold layers, plated lead-free solder layers/plated lead-free solder layers, plated lead-free solder layers/gold paste layers, and plated gold layers/plated gold layers. Particularly, the combinations of plated solder layers/plated solder layers, plated solder layers/plated nickel-gold layers, and plated tin layers/plated nickel-gold layers are preferred.

When the resin films have been provided for the purpose of protection, they are peeled after the low-melting conductive metal layers 33 are formed as described above.

The low-melting conductive metal layers 33 are formed on the connection terminals 30d and 30e, and the connection terminals 31a and 31b as described above. Subsequently, adhesive layers 35-1 and 35-2 are formed on mating surfaces at which the double-sided wiring boards 20-1 and 20-2 are bonded. Namely, the adhesive layers 35-1 and 35-2 are formed such that the connection terminals 30d and 30e will be exposed on the back surface of the double-sided wiring board 20-1 and the connection terminals 31a and 31b will be exposed on the front surface of the double-sided wiring board 20-2. The adhesive used in the present invention is a polyimide adhesive resin. The polyimide adhesive resin of the present invention contains hard segments having a polyimide group, and soft segments which bind the hard segments. The hard segment is a typical aromatic polyimide skeleton represented by Formula (I) below. The soft segment is a siloxane polyimide skeleton represented by Formula (II) below.

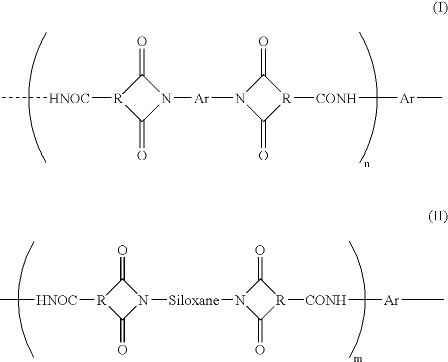

In Formulae (I) and (II), R is a hydrocarbon group, Ar is an aromatic group, Siloxane is a siloxane-derived group, and m and n are each an arbitrary integer.

The polyimide adhesive resins generally have a weight-average molecular weight of about 300,000 to 150,000.

The polyimide adhesive resin of the present invention contains a polyimide precursor and is a thermosetting resin. The polyimide adhesive resin preferably has a solubility parameter in the range of 17.5 to 22.5 (MJ/m³)^{1/2}, in which the polyamide adhesive resin shows very high affinity for polyimides that are possible materials of the double-sided wiring boards. The polyimide adhesive resin (cured) preferably has a tensile modulus in the range of 125 to 175 MPa, which reduces the possibility of deformed multilayer wiring board by internal stress resulting from the bonding. The solubility parameter and tensile modulus of the polyimide adhesive resin may be controlled by the structure of the soft segments of the polyimide adhesive resin, and the number of elements constituting the main chain of the resin. Examples of the polyimide adhesive resins include SN-9000 manufactured by Hitachi Chemical Co., Ltd., and UPICOAT FS-100L and UPICOAT FS-510 manufactured by UBE INDUSTRIES, LTD. The viscosity of the polyimide adhesive resins is preferably adjusted with methylpyrrolidone, γ-butyrolactone, epoxy resins and the like.

The polyimide adhesive resin is applied to the back surface of the double-sided wiring board 20-1 such that the connection terminals 30d and 30e will be exposed. The polyimide adhesive resin is applied to the front surface of the double-sided wiring board 20-2 such that the connection terminals 31a and 31b will be exposed. In the present invention, it is necessary that the polyimide adhesive resin be applied such that the connection terminals will be exposed on the bonding surfaces of the double-sided wiring boards. The selective application of the polyimide adhesive resin can be performed using screen masks. Specifically, the screen masks cover the areas including the connection terminals that should avoid the application of the polyimide adhesive resin, and the polyimide adhesive resin is selectively applied to desired areas. In the event that the masks used in the plating of the low-melting conductive metal layers 33 are a temporarily cured polyimide adhesive resin, the temporarily cured polyimide adhesive resin layers may be used as adhesive layers.

The polyimide adhesive resin is desirably applied in a thickness that is substantially the same level as the surface of the connection terminals 30d and 30e, and the surface of the connection terminals 31a and 31b. The thickness (as measured after the solvent is removed) is generally from 5 to 20 μm, preferably from 10 to 15 μm.

The adhesive layers 35-1 and 35-2 are formed on the double-sided wiring boards 20-1 and 20-2, respectively, as described above. The double-sided wiring boards are arranged such that the adhesive layers 35-1 and 35-2 are opposed and further such that the connection terminals 30d and 30e on the double-sided wiring board 20-1 are faced to the connection terminals 31b and 31a on the double-sided wiring board 20-2 each other. Subsequently, the double-sided wiring board 20-1 and the double-sided wiring board 20-2 are pressed against one another with heating. The heating temperature is at least the curing temperature of the polyimide adhesive resin in order that the double-sided wiring boards are bonded, and is generally in the range of 150 to 300° C., preferably 190 to 250° C. The wiring boards are pressed against one another at a pressure of about 1 to 4 kg/cm² at the above temperature for 1 to 20 seconds, preferably 5 to 10 seconds. Consequently, the polyimide adhesive resin develops adhesion between the double-sided wiring boards 20-1 and 20-2 and forms an adhesive layer 35 which bonds and integrates the double-sided wiring boards 20-1 and 20-2. The laminate in which the double-sided wiring boards 20-1 and 20-2 are bonded and integrated with the polyimide adhesive resin may be subjected to additional heating and pressing as required, whereby the bond strength of the laminate may be improved.

The heating under pressure, optionally accompanied by application of ultrasonic waves, melts the metals or alloys of the low-melting conductive metal layers 33 on the mating connection terminals 30d and 31b, and the mating connection terminals 30e and 31a. Consequently, the conductive metal layers in contact with each other are unified to form connection metal layers 34. The connection metal layers 34 electrically connect the double-sided wiring boards 20-1 and 20-2.

Although the above multilayer wiring board comprises two double-sided wiring boards, more wiring boards may be added by laminating double-sided wiring boards or one-sided wiring boards in a similar manner.

Alternatively, wiring boards may be increased by laminating the multilayer wiring boards thus manufactured through an insulating layer. Still alternatively, a combination of the provision of an insulating resin layer, masking and selective plating on the surface of the thus manufactured multilayer wiring board increases the number of wiring boards. Wiring boards may be added to the multilayer wiring board on which electronic components are mounted.

To ensure conduction through the thickness of the multilayer wiring board, additional electrical connection means may be provided through the thickness of the multilayer wiring board. As an example, via holes may be made by punching or laser beam application followed by desmearing as required, and the inner walls of the formed via holes may be plated with a conductive metal. Instead of the plating, the via holes may be filled with a conductive metal, or a conductive metal may be inserted in the via holes.

Although the above embodiments are focused on the double-sided wiring boards in which the wiring patterns are formed on both surfaces of the insulating substrate, the multilayer wiring board of the present invention may have, for example, two double-sided wiring boards one or both of which are free of a wiring pattern on the outermost surface of the insulating substrate.

Various modifications to the multilayer wiring boards of the present invention are possible.

For example, in the above description, the electrical connection between the front and back surfaces of the double-sided wiring board is established by punching the conductive metal foil and the substrate simultaneously, whereby the conductive metal pieces are punched out and are inserted in the through holes in the substrate to electrically connect the front and back surfaces of the substrate. Alternatively, through holes may be made in the substrate by punching or laser beam application, and a conductive metal may be selectively deposited on the inner walls of the through holes to establish an electrical connection between the front and back surfaces of the substrate. Instead of the deposition, the through holes may be filled with a conductive paste containing a large amount of a conductive metal to establish an electrical connection between the front and back surfaces of the substrate.

One or more electronic components may be mounted on the double-sided wiring boards in which the wiring patterns are formed on both surfaces of the insulating substrate.

When the double-sided wiring boards of the present invention are flexible tapes, the tapes may be provided with sprocket holes along the edges on both sides so that the tapes can be transferred. Positioning holes may be provided for alignment.

The wiring patterns on the surface of the multilayer wiring boards of the present invention may be surface treated as required, for example by plating. The wiring patterns may be protected with a solder resist layer while exposing the terminals. The multilayer wiring boards may be provided with outer terminals such as outer leads and outer pads.

The multilayer wiring boards can be used for the mounting of electronic components.

According to the present invention, a plurality of double-sided wiring boards may be easily laminated while establishing highly reliable electrical connection between the wiring boards. The multilayer wiring boards of the present invention have high reliability.

### INDUSTRIAL APPLICABILITY

According to the present invention, the multilayer wiring board having high reliability may be obtained through very simple steps. That is to say, the wiring patterns on both surfaces of the insulating substrate are electrically connected through the conductive metal pieces inserted in the via holes. The multilayer wiring board is producible very easily. Specifically, the electrical connection between the double-sided wiring boards is established through the plated layers made of specific low-melting conductive metals. The plated layers of low-melting conductive metals ensure electrical connection through the thickness of the multilayer wiring board. The double-sided wiring boards are laminated by means of a specific polyimide adhesive resin, and consequently the multilayer wiring board is not deformed and achieves high reliability.

### EXAMPLES

The multilayer wiring boards according to the present invention will be described in more detail by Examples without limiting the scope of the present invention.

### Example 1

An insulating substrate was a polyimide film 50 μm in thickness. The polyimide film had copper layers 12 μm in thickness on both surfaces. This double-sided copper clad laminate (35 mm wide) was provided with sprocket holes along the edges on both sides in the width direction.

The double-sided copper clad laminate (total thickness: 74 μm) was perforated to produce punching holes 100 μm in diameter. A rolled copper foil having an average thickness of 100 μm was overlaid on the surface of the laminate, and the rolled copper foil was punched with punches 100 μm in diameter. The pieces of the rolled copper foil punched out were inserted to remain in the punching holes. Consequently, the front and back surfaces of the double-sided copper clad laminate were electrically connected.

After the pieces punched out were inserted in the punching holes, the copper layers of the double-sided copper clad laminate were plated with copper in a thickness of 3 μm. Then, a photoresist was applied to the plated copper layers and exposed to light and developed to form desired patterns.

The plated copper layers were selectively etched using the patterns as masks, and wiring patterns were formed on both surfaces of the double-sided copper clad laminate. The wiring patterns included the punching holes in which the pieces punched out were inserted. Consequently, the wiring patterns were electrically connected through the pieces.

A polyimide adhesive resin (SN-9000 manufactured by Hitachi Chemical Co., Ltd.) was applied through screen masks such that parts of the wiring patterns would be exposed. The exposed parts of the wiring patterns included the punching holes on the connection surfaces of the double-sided wiring board and were capable of electrical connection when boards are laminated. The polyimide adhesive resin was applied such that the dry thickness would be 15 μm. The polyimide adhesive resin was heated at 120° C. for 5 minutes, and was temporarily cured. The double-sided wiring board masked with the temporarily cured polyimide adhesive resin was immersed in a solder plating bath. Consequently, the parts of the wiring patterns for electrical connection were plated with a low-melting conductive metal, namely solder, in a thickness of 3 μm.

Two double-sided wiring boards were arranged such that the temporarily cured polyimide adhesive resin layers would be faced to each other. The polyimide adhesive resin was cured by heating at 250° C. for 10 seconds. Consequently, the wiring boards were bonded together and the plated solder layers that were connection terminals were molten to establish an electrical connection between the wiring boards.

The polyimide adhesive resin contained hard segments forming polyimide bonds, and soft segments with siloxane bonds represented by Formula (II) above that bound the polyimide bonds. The polyimide adhesive resin was separately measured for a dielectric constant of cured product, resulting in 1 MHz:ε=3.38 and Tan δ=0.019. The polyimide adhesive resin had a solubility parameter of 19 (MJ/m³)^{1/2} and a tensile modulus of 140 MPa. The polyimide adhesive resin was separately measured for a bonding strength with respect to a polyimide film, resulting in 450 g/25 mm.

The multilayer wiring board produced as above had little resistance variation between the front and back surfaces, and proved very high reliability.

### Example 2

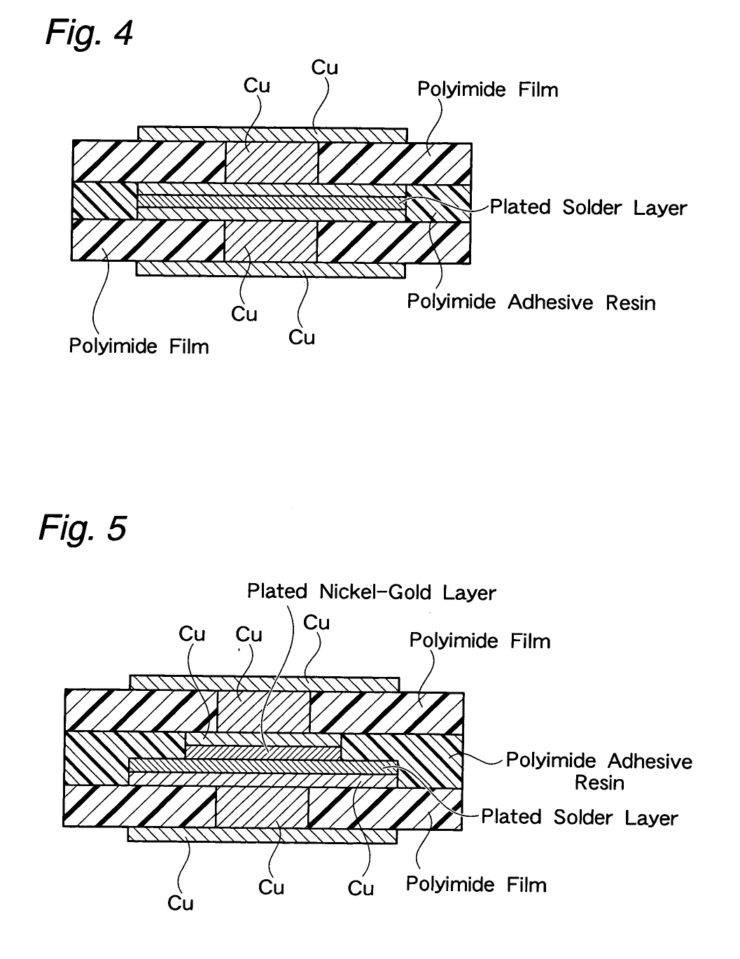

A multilayer wiring board as shown in FIG. 4 was manufactured in the same manner as in Example 1. The multilayer wiring board was subjected to a corrosion resistance test (PCT test: 2.5 atm, 127° C., 100% RH, 120 hr), a temperature characteristic test 1 (hot oil test: 10 cycles of 260° C. (5 sec) and 23° C. (15 sec)), and a temperature characteristic test 2 (reflow test: 3 cycles of 260° C. (10 sec)). Changes of resistance across the thickness of the multilayer wiring board were measured.

100 samples were measured for resistance before and after the tests. An objective change of resistance was not more than 10 mΩ/via hole. All the samples showed resistance changes within the range of ±10%. The results of the PCT test, hot oil test and reflow test of the 100 samples are given in Table 1.

TABLE 1

| Test Item | Resistance change after test |
|---|---|
| PCT test | 10% |
| Hot oil test | 5% |
| Reflow test | 6% |

### Example 3

A double-sided wiring board with a plated nickel-gold layer, and a double-sided wiring board with a plated solder layer were laminated together, and electrical connection was established in the same manner as in Example 1. Resultant multilayer wiring board is shown in FIG. 5.

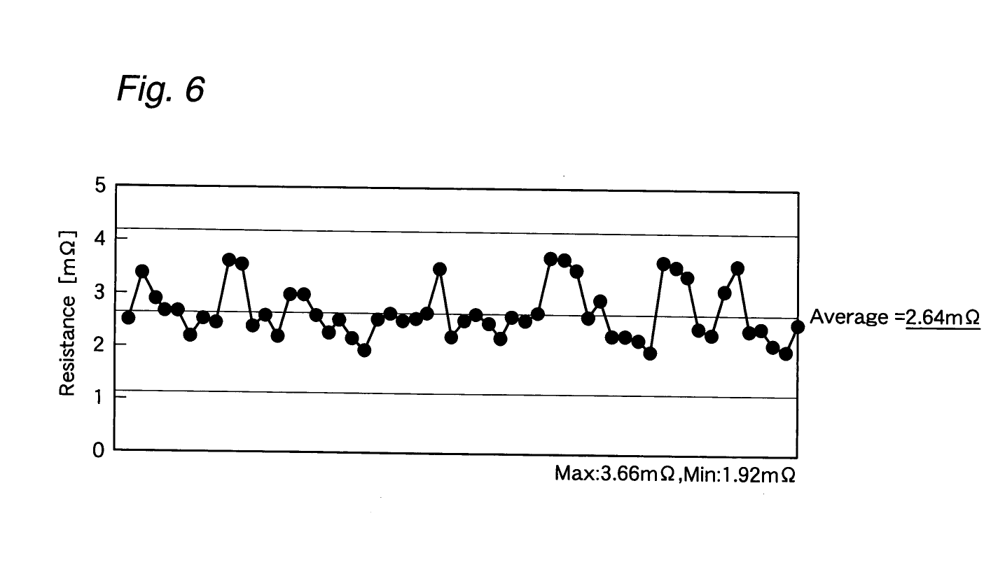

The multilayer wiring board was measured for resistance across thickness. An objective resistance variation was not more than 10 mΩ. The results are shown in FIG. 6.

As shown in FIG. 6, the average electrical resistance was 2.25 mΩ, with 3.66 mΩ maximum and 1.92 mΩ minimum. The double-sided wiring boards had little resistance variation and proved excellent electrical properties.

### Example 4

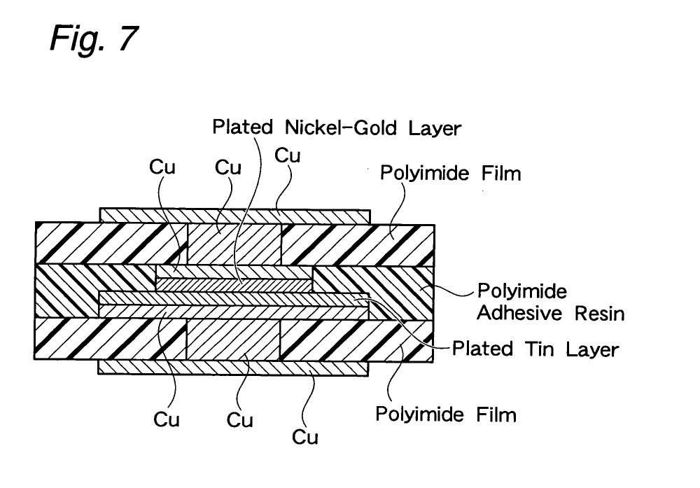

A double-sided wiring board with a plated tin layer, and a double-sided wiring board with a plated nickel-gold layer were laminated together, and electrical connection was established in the same manner as in Example 1. Resultant multilayer wiring board is shown in FIG. 7.

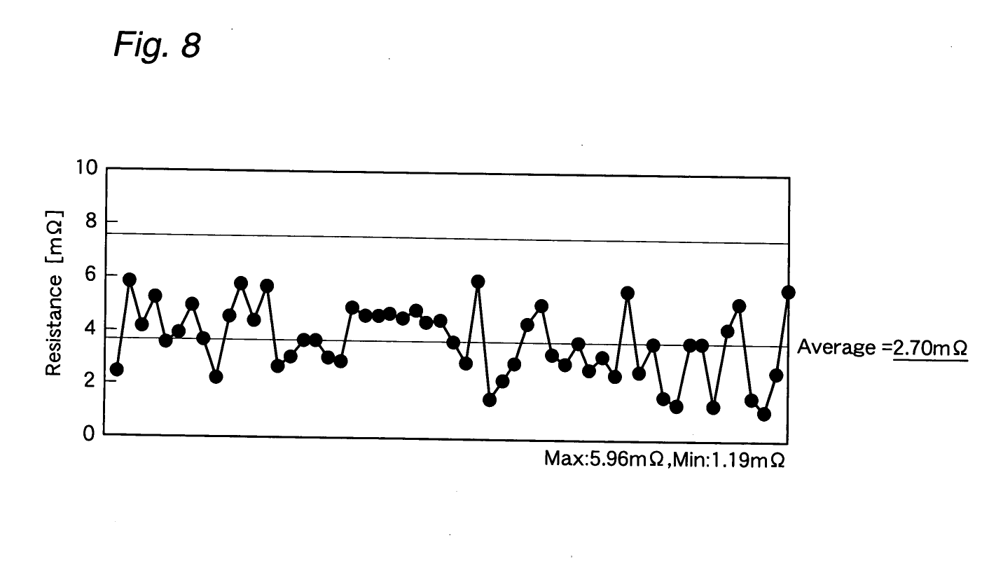

The multilayer wiring board was measured for resistance across thickness. An objective resistance variation was not more than 10 mΩ. The results are shown in FIG. 8.

As shown in FIG. 8, the average electrical resistance was 3.75 mΩ, with 5.96 mΩ maximum and 1.19 mΩ minimum. The double-sided wiring boards had little resistance variation and proved excellent electrical properties.

1. A multilayer wiring board comprising at least two wiring boards,
each of the wiring boards comprising an insulating substrate and a wiring pattern which comprises a conductive metal,
at least one of the at least two wiring boards having the wiring patterns on both surfaces of the insulating substrate,
at least part of the wiring patterns on the insulating substrate being connected via a conductive metal in a through hole through the insulating substrate,
the wiring boards being electrically connected by joining of low-melting conductive metal layers on connection terminals at the mating surfaces of the wiring boards, and
the at least two wiring boards being bonded by means of a polyimide adhesive resin that is selectively applied by screen printing on the wiring boards other than on the connection terminals.

2. The multilayer wiring board according to claim 1, wherein the polyimide adhesive resin includes a heat-curable polyimide.

3. The multilayer wiring board according to claim 1, wherein the polyimide adhesive gives a cured product having a dielectric constant of 3.1 to 3.7.

4. The multilayer wiring board according to claim 1, wherein the conductive metal is inserted in the through hole through the insulating substrate by steps comprising:
placing a conductive metal foil on an insulating substrate, the conductive metal foil having a thickness equal to or greater than that of the insulating substrate; and
punching the conductive metal foil, said punching punching out a conductive metal piece, the conductive metal piece punching out the insulating substrate and being inserted in the hole punched in the insulating substrate to electrically connect the front and back surfaces of the insulating substrate;
or wherein the conductive metal is inserted in the through hole through the insulating substrate by steps comprising:
placing a conductive metal foil on an insulating substrate, the insulating substrate having a punching hole, the conductive metal foil having a thickness equal to or greater than that of the insulating substrate; and
punching the conductive metal foil, said punching punching out a conductive metal piece and being inserted in the punching hole in the insulating substrate to electrically connect the front and back surfaces of the insulating substrate.

5. The multilayer wiring board according to claim 1, wherein the conductive metal is inserted in the through hole through the insulating substrate by steps comprising:
placing a conductive metal foil on a metal clad laminate, the conductive metal foil having a thickness equal to or greater than that of the metal clad laminate; and
punching the conductive metal foil, said punching punching out a conductive metal piece, the conductive metal piece punching out the insulating substrate and being inserted in the hole punched in the metal clad laminate to electrically connect the front and back surfaces of the insulating substrate;
or wherein the conductive metal is inserted in the through hole through the insulating substrate by steps comprising:
placing a conductive metal foil on a metal clad laminate, the metal clad laminate having a punching hole, the conductive metal foil having a thickness equal to or greater than that of the metal clad laminate; and
punching the conductive metal foil, said punching punching out a conductive metal piece and being inserted in the punching hole in the metal clad laminate to electrically connect the front and back surfaces of the insulating substrate.

6. The multilayer wiring board according to claim 1, wherein the insulating substrate is an insulating resin film having flexibility.

7. The multilayer wiring board according to claim 1, wherein the low-melting conductive metal layer is at least one plated metal layer selected from the group consisting of plated solder layer, plated lead-free solder layer, plated tin layer, plated gold layer and plated nickel-gold layer.

8. The multilayer wiring board according to claim 1, wherein a first conductive metal layer on an electrical connection surface of a wiring board, and a second conductive metal layer on an electrical connection surface of a mating wiring board electrically connected with the wiring board have at least one combination selected from the group consisting of plated solder layer/plated nickel-gold layer, plated tin layer/plated nickel-gold layer, plated solder layer/plated solder layer, plated tin layer/plated nickel-gold layer, plated lead-free solder layer/plated lead-free solder layer, plated lead-free solder layer/gold paste layer, and plated gold layer/plated gold layer.

9. The multilayer wiring board according to claim 1, wherein the wiring patterns comprise a conductive metal containing copper or a copper alloy.

10. The multilayer wiring board according to claim 1, wherein the conductive metal inserted in the through hole through the insulating substrate contains copper or a copper alloy.

11. The multilayer wiring board according to claim 2, wherein the polyimide adhesive gives a cured product having a dielectric constant of 3.1 to 3.7.

12. The multilayer wiring board according to claim 4, wherein the insulating substrate is an insulating resin film having flexibility.
